(19) United States
(12) Patent Application Publication
(10) Pub. No.: US 2017/0359067 A1
(43) Pub. Date: Dec. 14, 2017

(54) OPERATING DEVICE, IN PARTICULAR FOR AN ELECTRONIC HOUSEHOLD APPLIANCE

(71) Applicant: DIEHL AKO STIFTUNG & CO. KG, Wangen (DE)

(72) Inventors: JOACHIM LYSZUS, BAINDT (DE); BRUNO FUHGE, ACHBERG (DE)

(21) Appl. No.: 15/687,574

(22) Filed: Aug. 28, 2017

Related U.S. Application Data
(63) Continuation of application No. PCT/EP2015/000447, filed on Feb. 26, 2015.

(51) Int. Cl. H03K 17/969; F21V 8/00; F21V 5/04; F21V 17/10; H05K 5/03

(52) U.S. Cl. CPC H03K 17/969; F21V 5/04; F21V 17/101; G02B 6/0001; H05K 5/03; H03K 2217/9655

(57) ABSTRACT

An operating device for electronic household appliances has a cover plate with an operating section that is elastically deformable and/or movable with the operating section. A carrier plate is arranged on a side of the cover plate facing away from a user side and at a spacing distance from the cover plate. A sensor on the carrier plate detects a distance variation from the inner side of the cover plate in the region of the operating section of the cover plate. A geometrically stable light guide element is furthermore provided, which extends in a region outside the operating section of the cover plate from the cover plate to the carrier plate. The cover plate has a signal section that is at least partially light-transmissive in the region of the light guide element.

### CROSS-REFERENCE TO RELATED APPLICATION

This application is a continuation, under 35 U.S.C. §120, of copending international application No. PCT/EP2015/000447, filed Feb. 26, 2015, which designated the United States; the prior application is herewith incorporated by reference in its entirety.

### BACKGROUND OF THE INVENTION

### Field of the Invention

The present invention relates to an operating device, in particular an operating device for electronic household appliances.

For operating devices, various types of operating elements having different functionalities are known. In the case of operating elements configured as buttons, for example, distinction may be made between touch-sensitive and/or proximity-sensitive buttons (so-called touch control) and buttons that can be actuated by the action of force, these being producible respectively with different structures and functionalities.

In this context, besides those having a mechanical actuation element, in the case of buttons that can be actuated by the action of force, capacitive buttons (see, for example, German published patent application DE 10 2011 121 897 A1), inductive buttons (see, for example, U.S. published patent application US 2011/0187204 A1 and its counterpart European patent EP 2 529 484 B1) and piezoelectric buttons (see, for example, U.S. published patent application US 2009/0238375 A1 and its counterpart European patent EP 2 063 533 B1) are also known in particular. These special buttons generally require a high manufacturing and assembly accuracy with small tolerance ranges. Furthermore, buttons having optical sensor systems have also recently been developed.

### SUMMARY OF THE INVENTION

It is accordingly an object of the invention to provide an operating device which overcomes the above-mentioned and other disadvantages of the heretofore-known devices and methods of this general type and which provides for an operating device having a button that can be actuated by the action of force, which has an identification for the user and is constructed as simply as possible.

With the foregoing and other objects in view there is provided, in accordance with the invention, an operating device, in particular for a household applicance. The operating device comprises:

a cover plate having a user side facing toward a user, and an inner side facing away from the user, the cover plate defining an operating section within which the cover plate is at least partially elastically deformable and/or movable;

a carrier plate disposed at a spacing distance from the inner side of the cover plate;

a sensor disposed on the carrier plate and configured to detect a variation in a distance from the inner side of the cover plate in a region of the operating section of the cover plate; and a geometrically stable light guide element extending between the cover plate and the carrier plate in a region outside the operating section of the cover plate, and the cover plate being formed with a signal section that is at least partially light-transmissive in a region of the light guide element.

In other words, the operating device of the invention includes: a cover plate having a user side facing toward a user, and an inner side facing away from the user, the cover plate defining an operating section and being configured to be at least partially elastically deformable and/or movable in this operating section; a carrier plate, which is arranged on a side of the cover plate facing away from the user side and at a distance from this plate; a sensor, which is provided on the carrier plate and is configured and arranged in such a way that it can detect a distance variation from the inner side of the cover plate in the region of the operating section of the cover plate; and a geometrically stable light guide element, which extends in a region outside the operating section of the cover plate from the cover plate to the carrier plate, the cover plate comprising a signal section, which is configured to be at least partially light-transmissive, in the region of the light guide element.

The operating device according to the invention comprises a signal section in the vicinity of the operating section, by which the operating section can be visually identified for the user. The signal section preferably also provides the possibility of not only identifying the operating section, but also imparting further information to the user, for example regarding the operating state of the operating section or of the household appliance.

In the operating device according to the invention, a geometrically stable light guide element extends in a region outside the operating section of the cover plate from the cover plate to the carrier plate. The light guide element is coupled to the signal section of the cover plate and therefore reinforces the visual identification of the operating section of the operating device. Furthermore, the geometrically stable light guide element bears on the one hand against the carrier plate and on the other hand against the cover plate, so that it also fulfills the function of a mechanical support. The region outside the operating section, which can deform or move under the action of force, is thus mechanically stabilized by the light guide element. The operating section of the cover plate can thus be mechanically decoupled more reliably from the other regions of the cover plate, so that actuation of the operating section by a user can be detected more reliably by the sensor.

The cover plate may, in this context, in principle be made of any desired material (for example transparent or opaque, electrically conductive or electrically nonconductive, etc.), with any desired dimensions and with any desired design. The operating device according to the invention is, however, also suitable in particular for use with metal cover plates. The cover plate is preferably a control panel, for example of an electronic household appliance.

The operating section is preferably formed in one piece with the cover plate, fitted as a separate component into the cover plate, or connected as a separate component firmly to the cover plate. The operating section defines for the user an operating element of the operating device, which he must press for actuation. That is to say, the operating section forms a button that can be actuated by the action of force. The operating section may preferably also be made identifiable for the user, preferably by special shaping of its user side (haptic identification), identification with colors and/or symbols, and the like.

The operating section is at least partially elastically deformable and/or movable by a force action from the user side of the cover plate. The elastic deformability is preferably achieved by a special material selection and/or special dimensioning (particularly in the thickness direction) of the operating section. The elastic movability may preferably be produced by sprung mounting of the operating section in an opening in the cover plate.

The carrier plate is preferably configured as a printed circuit board. The sensor is arranged on a side of the carrier plate facing toward the cover plate, and/or on a side of the carrier plate facing away from the cover plate. The carrier plate is preferably arranged essentially parallel to the cover plate. A control device for controlling the sensor and receiving the measurement signals of the sensor is preferably also arranged on the cover plate.

The light guide element between the cover plate and the carrier plate is configured to be geometrically stable. In this context, the term geometrical stability refers to a stably constant shape and dimension of the light guide element during intended use of the operating device, i.e. in particular during intended force actions (for example for actuation of the buttons) and intended temperature ranges. By the geometrical stability of the light guide element, deformation or movement of the cover plate in a region outside the operating section—independently of the configuration of the cover plate in that region—can be suppressed or at least greatly restricted. The button functionality can therefore be restricted to the operating section, and “crosstalk” with for example other operating sections of the cover plate can be prevented.

The light guide element is configured in such a way that it guides light, particularly light in the visible wavelength range, from an input face of the light guide element to an output face of the light guide element with the smallest possible (intensity) loss. The input face of the light guide element is preferably coupled to at least one light source, preferably in the form of a light-emitting diode, on the carrier plate. The output face of the light guide element is coupled to the signal section, or to its light-transmissive subregions. The light guide element is preferably made of a plastic material. The operating device may preferably comprise one or more light guide elements.

The signal section of the cover plate is intended to visually identify the operating section of the cover plate for the user. In one configuration, the signal section encloses the operating section essentially fully, or at least in subsections. In other configurations, the signal section represents a symbol or a 7-segment display.

Besides the button that can be actuated by the action of force, the actuation of which is detected by the sensor, the operating device according to the invention may optionally contain further operating elements having different functionalities. In this case, in particular, touch-sensitive and/or proximity-sensitive buttons may be used.

In one preferred configuration of the invention, the sensor is an optical sensor. The optical sensor preferably comprises at least one transmitter for emitting electromagnetic radiation and at least one receiver for detecting the electromagnetic radiation. The sensor in this case preferably uses electromagnetic radiation in a different wavelength range, preferably in the infrared range, than the light guide element. In this configuration, the light guide element is furthermore preferably configured in such a way that it absorbs, preferably almost completely absorbs, the electromagnetic radiation used by the sensor. In this way, it is possible to prevent the light for identifying the operating section from influencing the measurement values of the sensor. In the operating device according to the invention having an optical sensor, minimal deformations or movement excursions of the operating section are sufficient in order to be able to detect actuation by the user, since even very small variations of the reflection positions on the operating section cause very different deviations of the electromagnetic radiation. Actuation of the operating section can therefore be detected very reliably. In this design, furthermore, the tolerances during manufacture and assembly of the component parts may be greater compared with conventional buttons with a capacitive, inductive or piezoelectric functionality, which can be actuated by the action of force. Since, for the detection of actuation of the operating section, it is sufficient to detect a relative variation of the detection position of the reflected radiation, a calibration process may also be obviated with an operating device constructed in this way.

When an optical sensor is used, the inner side of the cover plate is preferably configured with a reflection face in the region of the operating section. The reflection face of the operating section is preferably configured in such a way that it can at least partially reflect the radiation emitted by the transmitter. This reflection property is preferably achieved by a special material selection, a special surface structure, a special surface treatment (preferably coating, etc.) of the inner side of the cover plate, or the like. The reflection face is preferably provided only in the region of the operating section, although as an alternative it may also be formed over the entire cover plate.

The transmitter of the sensor preferably comprises light-emitting diodes, laser diodes, incandescent lamps, halogen lamps, or the like. The receiver preferably allows position-resolved detection of the reflected radiation. The receiver is therefore preferably selected from CCD chips, active pixel sensors, photodiodes, phototransistors, etc., and arrangements of such elements.

In another preferred configuration of the invention, a lens element is arranged between the sensor and the cover plate. This lens element is preferably intended to improve the performance and the functionality of the sensor. In this configuration, the lens element is preferably formed integrally with the light guide element, i.e. preferably formed in one piece therewith or formed thereon.

In another preferred configuration of the invention, the sensor comprises a sensor housing. The sensor housing may preferably comprise recesses for receiving the transmitter and the receiver of the sensor. The sensor housing is preferably configured in the form of a plate or frame. The sensor housing may preferably serve for optical separation between the transmitter and the receiver and/or for mechanical protection of the sensor components. In this configuration, the sensor housing is preferably formed integrally with the light guide element, i.e. preferably configured in one piece therewith or formed thereon.

In one preferred configuration of the invention, the signal section of the cover plate comprises at least one opening. This configuration is advantageous in particular for cover plates made of an opaque material. The at least one opening of the signal section is preferably closed with a light-transmissive casting compound, for example made of a transparent adhesive or synthetic resin.

In one preferred configuration of the invention, the light guide element comprises first latching devices (for example latching hooks), which are engaged with second latching devices (for example hooks or holes) on the carrier plate.

In another preferred configuration of the invention, the light guide element is adhesively bonded to the cover plate.

In yet another preferred configuration of the invention, the cover plate defines a plurality of mutually separated operating sections next to one another, a plurality of sensors are arranged next to one another on the carrier plate in a manner corresponding to the plurality of operating sections, and geometrically stable light guide elements are respectively provided in regions between the plurality of operating sections. By use of the geometrically stable light guide elements, the distance between neighboring operating sections can be selected to be relatively small, without the risk of crosstalk between the neighboring buttons arising. In this way, it is even possible to produce operating devices in the manner of a slider.

The invention also relates to an electronic household appliance having at least one operating device of the invention as described above.

The electronic household appliance is preferably a laundry appliance (washing machine, washer-dryer, dryer, etc.), a dishwasher, a refrigerator and/or freezer appliance, a stovetop, a cooker, a microwave oven, an exhaust hood, or the like.

Other features which are considered as characteristic for the invention are set forth in the appended claims.

Although the invention is illustrated and described herein as embodied in an operating device, in particular for an electronic household appliance, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE SEVERAL VIEWS OF THE DRAWING

FIG. 1 is a perspective sectional view of an operating device according to a first exemplary embodiment of the invention;

FIGS. 2A and 2B are a very simplified representations of the functional principle of the operating device according to one preferred alternative embodiment, with FIG. 2A showing the unactuated functional state and FIG. 2B showing the actuated functional state;

FIG. 3 is a perspective view of an operating device of the operating device to explain the assembly of the operating device;

FIG. 4 is a perspective sectional view of an operating device according to a second exemplary embodiment of the invention; and

FIG. 5 is a partial perspective view of an operating device according to a third exemplary embodiment of the invention.

### DETAILED DESCRIPTION OF THE INVENTION

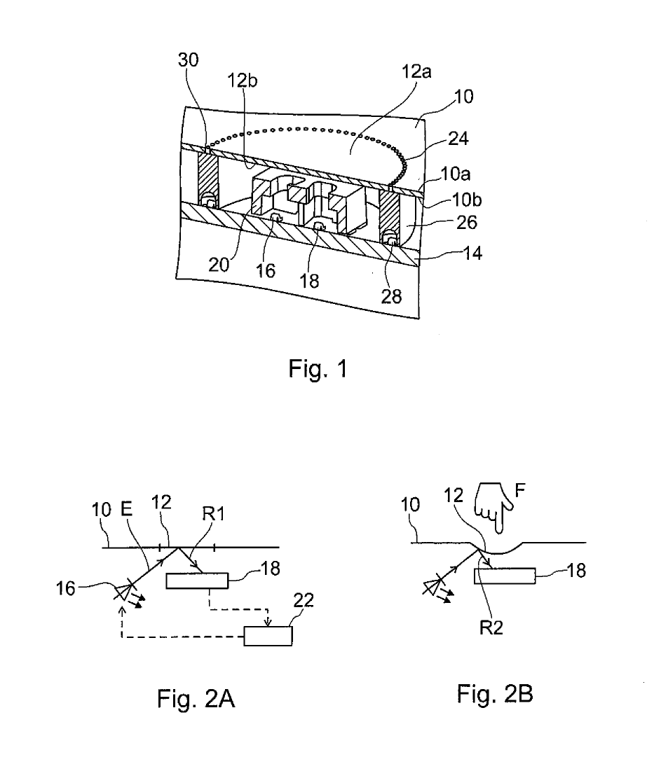

Referring now to the figures of the drawing in detail and first, particularly, to FIGS. 1 and 2 (i.e., 2A, 2B) thereof, there is shown a first exemplary embodiment of an operating device configured according to the invention.

The operating device comprises a cover plate 10 in the form of a control panel. The cover plate 10 is, for example, made of metal (for example sheet stainless steel) or an opaque plastic material. The cover plate 10 has a user side 10a facing toward the user (at the top in FIG. 1), which corresponds to the outer side of the control panel, and an inner side 10b facing away from the user (at the bottom in FIG. 1).

The cover plate 10 comprises an operating section 12a, which defines an operating element for the user, which he can actuate. The operating section 12a is integrated into the cover plate 10, or formed in one piece therewith, or fitted as a separate component therein and optionally connected thereto. As is shown by a comparison between FIGS. 2A and 2B, the operating section 12a is configured to be elastically deformable or movable by a force action F from the user side 10a, for example with a finger of the user. That is to say, after the end of the force action F, the operating section 12a returns into its initial state of FIG. 1 or 2A.

The operating device furthermore comprises a carrier plate 14 in the form of a printed circuit board. This carrier plate 14 is essentially oriented parallel to the cover plate 10 and arranged at a distance therefrom on the side of the cover plate 10 facing away from the user side 10a. On this carrier plate 14—in this exemplary embodiment on its side facing toward the cover plate 10—a sensor is arranged in a position corresponding to the operating section 12a.

In this exemplary embodiment, the sensor is configured as an optical sensor which comprises a transmitter 16, for example in the form of a light-emitting diode, and a receiver 18, for example in the form of a CCD chip. The transmitter 16 emits electromagnetic radiation, preferably in the visible or infrared wavelength range, and the receiver 18 detects electromagnetic radiation of the same wavelength range.

As illustrated in FIG. 2, the radiation E emitted by the transmitter 16 strikes the inner side 10b of the cover plate 10, which is provided with a reflection face 12b in the region of the operating section 12a. The radiation E is thus reflected at the operating section 12, and the reflected radiation R1, R2 then strikes the receiver 18 and is detected thereby. The receiver 18 is configured in such a way that it can detect the electromagnetic radiation in a positionally resolved manner. In the initial state of FIG. 2A, i.e. without an actuation of the operating section 12a by the user, the operating section 12a is in its undeformed initial state and the reflection face 12b reflects the radiation R1 to the receiver 18. In the actuation state of FIG. 2B, i.e. in the event of a force action F by the user on the operating section 12a, the operating section 12a is deformed and the reflection face 12b reflects the radiation R2 to the receiver 18. The comparison between FIGS. 2A and 2B shows that even in the event of a small deformation of the operating section 12a, a very significant variation of the detection position of the reflected radiation R2 already takes place. This relative variation of the detection position is detected by the position-resolving receiver 18. The control device 22, which is connected in a wired or wireless fashion to the transmitter 16 and to the receiver 18 and may for example likewise be arranged on the carrier plate 14, controls the transmitter 16 and evaluates the measurement signals generated by the receiver 18.

As represented in FIG. 1, the sensor also comprises a sensor housing 20, which is substantially configured in the form of a plate or frame and is mounted on the carrier plate 14. The sensor housing 20 is formed with recesses for receiving the transmitter 16 and the receiver 18, which are separated from one another by a separating wall. The sensor housing 20 is preferably made of a plastic material. Furthermore, the sensor housing 20 is preferably configured to be essentially absorbent or nontransmissive for the electromagnetic radiation used by the sensor, in order to prevent direct optical closure between the transmitter 16 and the receiver 18.

The substantially circular operating section 12a of the cover plate 10 is surrounded by a substantially annular signal section 24. This signal section 24 comprises numerous openings 30, and is therefore configured to be light-transmissive. With this signal section 24, the operating section 12a can be visually identified for the user. Furthermore, for example, the operating state of the operating device may be displayed to the user with the aid of the signal section 24.

On the inner side 10b of the cover plate 10, a geometrically stable light guide element 26 is assigned to the signal section 24. The light guide element 26 is therefore likewise arranged outside the operating section 12a and is configured substantially annularly. The light guide element 26 extends from the cover plate 10, or its inner side 10b, to the carrier plate 14. In other words, the light guide element 26 bears on the one hand against the cover plate 10 and on the other hand against the carrier plate 14. Because of the geometrical stability of the light guide element 26, deformation or movement of the cover plate 10 in the region outside the operating section 12a is prevented.

The light guide element 26 is preferably made of a plastic material and configured in order to guide electromagnetic radiation in the visible wavelength range. The input face of the light guide element 26, facing toward the carrier plate 14, is coupled to one or more light sources 28, which are for example produced using light-emitting diodes on the carrier plate 14. The output face of the light guide element 26, facing toward the cover plate 10, is coupled to the signal section 24, or to its openings 30.

The openings 30 of the signal section 24 of the cover plate 10 are preferably cast with a transparent adhesive or synthetic resin. This casting compound may also be used as an adhesive bond between the cover plate 10 and the light guide element 26; as an alternative, an additional transparent adhesive layer may be provided in order to apply the required holding force.

The light guide element 26 is preferably configured in such a way that it preferably fully absorbs the electromagnetic radiation used by the sensor. Furthermore, a different wavelength range is preferably used for the light sources 28 than for the sensor. In this way, it is possible to prevent the light guide element 26 from interfering with the functionality of the sensor; instead, the light guide element 26 may be used as a shield of the sensor.

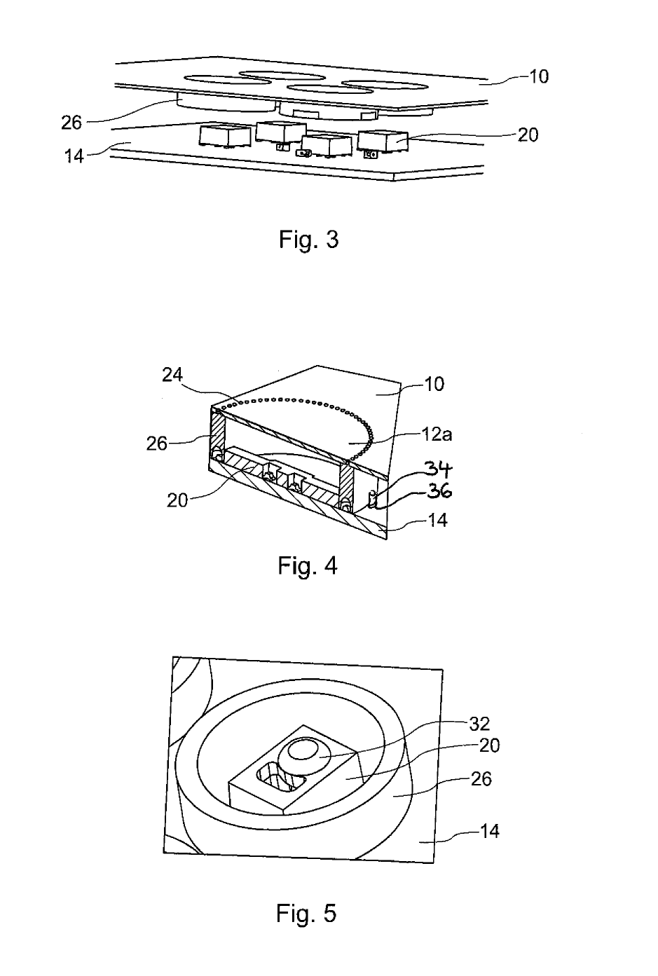

During production of the operating device, the light guide element 26 is initially adhesively bonded to the inner side 10b of the cover plate 10, as represented in FIG. 3. On the other hand, the sensors 16-20 and the light sources 28 are mounted on the carrier plate 14. Thus, a technical module and a design module may separately be prepared, and optionally tested, and then assembled.

The light guide element 26 is for example provided with latching lugs 34 as first latching devices, which may for example engage with holes 36 as second latching devices in the carrier plate 14. Thus, the carrier plate 14 with the electronics mounted thereon may be snap-fastened onto the light guide element 26 on the cover plate 10. Instead of the latching connection, clamp or screw connections may for example also be envisioned.

FIG. 4 shows a second exemplary embodiment of an operating device according to the invention. Components which are the same or correspond to one another are provided with the same references as in the first exemplary embodiment.

In the exemplary embodiment of FIG. 4, the sensor housing 20 of the sensor and the light guide element 26 are configured intricately with one another. Thus, for example, the two components 20, 26 may be manufactured in one piece with one another, or one component may be injection-molded onto the other component. If the two components are intended to be made from different plastic materials, 2C injection molding methods may for example be envisioned for this.

By the reduction of the number of separate component parts, the assembly process can be simplified in this exemplary embodiment.

FIG. 5 shows a third exemplary embodiment of an operating device according to the invention. Components which are the same or correspond to one another are provided with the same references as in the first exemplary embodiment.

In this exemplary embodiment, a lens element 32 is additionally provided between the sensor housing 20 and the cover plate 10.

This lens element 32 may preferably be formed integrally with the light guide element 26 and/or the sensor housing 20. In particular, the components 20, 26, 32 may be manufactured in one piece with one another, for example, or one component may be injection-molded onto the other component(s). If the components are intended to be made from different plastic materials, 2C injection molding methods may for example be envisioned for this.

By the reduction of the number of separate component parts, the assembly process can be simplified in this exemplary embodiment.

With the operating device according to the invention, particularly because of the geometrically stable light guide element 26 as a mechanical support, it is possible to arrange a plurality of buttons closely next to one another. Thus, the production of a slider having a plurality of buttons next to one another is also possible as a further exemplary embodiment of the invention.

The following is a summary list of reference numerals and the corresponding structure used in the above description of the invention:

cover plate

10a user side

10b inner side

12a operating section

12b reflection face

14 carrier plate

16 transmitter of a sensor

18 receiver of a sensor

20 sensor housing

22 control device

24 signal section

26 light guide element

28 light source

30 openings

32 lens element

34 latching lugs

36 latching holes

E emitted radiation

F force action

R1 reflected radiation

R2 reflected radiation

1. An operating device, comprising:
a cover plate having a user side facing toward a user, and an inner side facing away from the user, said cover plate defining an operating section within which said cover plate is at least partially elastically deformable and/or movable;
a carrier plate disposed at a spacing distance from said inner side of said cover plate;
a sensor disposed on said carrier plate and configured to detect a variation in a distance from said inner side of said cover plate in a region of said operating section of said cover plate; and
a geometrically stable light guide element extending between said cover plate and said carrier plate in a region outside said operating section of said cover plate, and said cover plate being formed with a signal section that is at least partially light-transmissive in a region of said light guide element.

2. The operating device according to claim 1, wherein:
said sensor is an optical sensor; and
said light guide element is configured to absorb electromagnetic radiation used by said sensor.

3. The operating device according to claim 2, which comprises a lens element arranged between said sensor and said cover plate, and said lens element being formed integrally with said light guide element.

4. The operating device according to claim 1, wherein said sensor comprises a sensor housing formed integrally with the light guide element.

5. The operating device according to claim 1, wherein:
said signal section of said cover plate is formed with at least one opening; and
said at least one opening of said signal section is closed with a light-transmissive casting compound.

6. The operating device according to claim 1, wherein said light guide element comprises first latching devices configured to engage with second latching devices of said carrier plate.

7. The operating device according to claim 1, wherein said light guide element is adhesively bonded to said cover plate.

8. The operating device according to claim 1, wherein:
said sensor comprises a transmitter for emitting electromagnetic radiation and a receiver for detecting the electromagnetic radiation; and
said receiver is configured to enable a position-resolved detection of the electromagnetic radiation emitted by said transmitter and reflected following the emission.

9. The operating device according to claim 1, wherein:
said cover plate defines a plurality of mutually separated operating sections next to one another;
a plurality of sensors disposed next to one another on said carrier plate; and
said geometrically stable light guide elements are disposed in regions between said operating sections.

10. The operating device according to claim 1 configured for an electronic household appliance.

11. An electronic household appliance, comprising at least one operating device according to claim 1.
